(19) United States
(12) Patent Application Publication
(10) Pub. No.: US 2011/0293924 A1
(43) Pub. Date: Dec. 1, 2011

(54) HOUSING STRUCTURE FOR ELECTRONIC DEVICE AND MANUFACTURING METHOD THEREOF

(75) Inventor: Wei-Yu Liao, Zhang Hua City (TW)

(73) Assignee: Kunshan Tong-yin Industrial Electronic Making Co., Ltd., Jiangsu Prov. (CN)

(21) Appl. No.: 13/114,235

(22) Filed: May 24, 2011

(30) Foreign Application Priority Data
May 27, 2010 (CN) 201010185138.5

(51) Int. Cl. H05K 5/02; B29C 65/70; B32B 9/00; B32B 1/02; B32B 7/12

(52) U.S. Cl. 428/332; 428/411.1; 428/408; 428/426; 156/245

(57) ABSTRACT

A housing structure for an electronic device and a manufacturing method thereof are disclosed. The housing structure includes a composite material panel. An inner surface of the composite material panel is coated with a film medium layer. One surface of the film medium layer is adhered to the inner surface of the composite material panel, and the other surface of the film medium layer is adhered with a plastic member. The method combines the composite material panel and the plastic member by way of the film medium layer as a medium to achieve the purpose of injection molding and adhering the plastic member on the composite material panel, and thereby obtaining the housing structure for an electronic device. In comparison with the prior art, the method can overcome the disadvantages of the composite material panel not able to be formed as a structural member having complicated structures.

### BACKGROUND OF THE INVENTION

1. Field of the Invention

The present invention relates a housing structure for an electronic device and a manufacturing method thereof, and more particular to a housing made of a composite material and a plastic material and a manufacturing method thereof.

2. The Prior Arts

The conventional housing for an electronic device is often made of a plastic material, and the disadvantage of unevenness may occur on the surface of the electronic device. As such, before being processed with a coating, plural processes of polishing and flattening have to be carried out for achieving the requirements for being served as a housing. The manufacturing processes become therefore more complicated, and anti-radiation performance is poor. In the market, some kinds of housing are made of metal materials. The metal-made housing is less likely to be broken when falling off. But since the operations of hole-punching and fixing need to be processed on the metal-made housing, the strength of the housing is therefore weakened, and the thickness and weight of the housing are increased. Another type of housing is made of carbon or glass fiber composite material. The housing made of the composite materials has advantages of high strength, thin thickness, light weight, and anti-corrosion, and also provides a better anti-radiation performance. However, it can only be formed as a panel for being used in appearance applications and can not be formed as a structural member having complicated structures.

### SUMMARY OF THE INVENTION

In order to overcome the aforementioned disadvantages, the present invention provides a housing structure for an electronic device and a manufacturing method thereof. The housing structure made by the manufacturing method of the present invention has advantages of high strength, thin thickness, light weight, anti-corrosion, and good anti-radiation performance, and can be formed as structural members having complicated structures.

One solution to the aforementioned disadvantages provided by the present invention is to provide a housing structure for an electronic device which comprises a composite material panel. An inner surface of the composite material panel is coated with a film medium layer. One surface of the film medium layer is adhered to the inner surface of the composite material panel, and the other surface of the film medium layer is adhered with a plastic member.

The film medium layer is a hot melt adhesive film.

The film medium layer has a thickness of 0.01-0.2 mm.

The composite material panel is one of a carbon fiber composite material panel, a glass fiber composite material panel, and a resin composite material panel.

A method for manufacturing a housing structure for an electronic device according to the present invention comprises the following steps:

A step of performing, stacking a sheet-like composite material, according to a required thickness and strength, to form a composite material stacked layer;

a step of film adhering, adhering a hot melt adhesive film on one surface of the composite material stacked layer;

a step of forming: putting the composite material stacked layer adhered with the hot melt adhesive film in a mold to be heated and pressurized, such that the composite material stacked layer is formed as a composite material panel with a desired shape, and the hot melt adhesive film is completely melted and adhered on one surface of the composite material panel; and

a step of injection molding: injection molding a plastic member on the hot melt adhesive film of the composite material panel, so as to be configured as the housing structure for an electronic device.

The step of forming is an air pressure forming. The step of forming is described as follows: The composite material stacked layer is put in a mold, and the surface of the composite material stacked layer adhered with the hot melt adhesive film is faced upwardly. A counterpart block is installed to completely press on the surface of the composite material stacked layer adhered with the hot melt adhesive film. A sealing film is coated on a top of the counterpart block. Then the mold is closed. Afterwards, the mold is heated and a mold cavity of the mold is simultaneously vacuumed to a predetermined value of pressure. When the temperature reaches a predetermined value, the mold cavity is inflated with air. The air pressure presses on to the top of the counterpart block and further to the composite material stacked layer adhered with the hot melt adhesive film. After heating for a period of time and followed by cooling, the mold is opened to obtain a solidified composite material panel with a desired shape. The hot melt adhesive film is adhered on one surface of the composite material panel by way of being melted by heating and then solidified by cooling.

After the step of forming and before the step of injection molding, the composite material panel is shaped by mold punching or computer numerical control machining to a desired shape and dimension.

In the step of film adhering, the thickness of the adhered hot melt adhesive film is 0.01˜0.2 mm.

The composite material may be one of a carbon fiber composite material, a glass fiber composite material, and resin composite material.

The composite material panel has advantages of high strength, thin thickness, light weight, anti-corrosion and anti-radiation, and the plastic member has features of light weight and easy to be machined. In comparison with the prior art, the present invention combines a composite material panel and a plastic member by way of a film medium layer as a medium to achieve the purpose of injection molding and adhering the plastic member on the composite material panel, and thereby obtaining a housing structure for an electronic device. The plastic member may have a complicated structure. The housing structure according to the present invention keeps the same advantages as those of the composite material panel. Additionally, the present invention can overcome the disadvantages of the composite material panel not able to be formed as a structural member having complicated structures.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a schematic structural view showing a housing structure for an electronic device according to the present invention; and

FIG. 2 is a schematic view showing a stacking relationship in the mold in a step of air pressure forming, according to the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

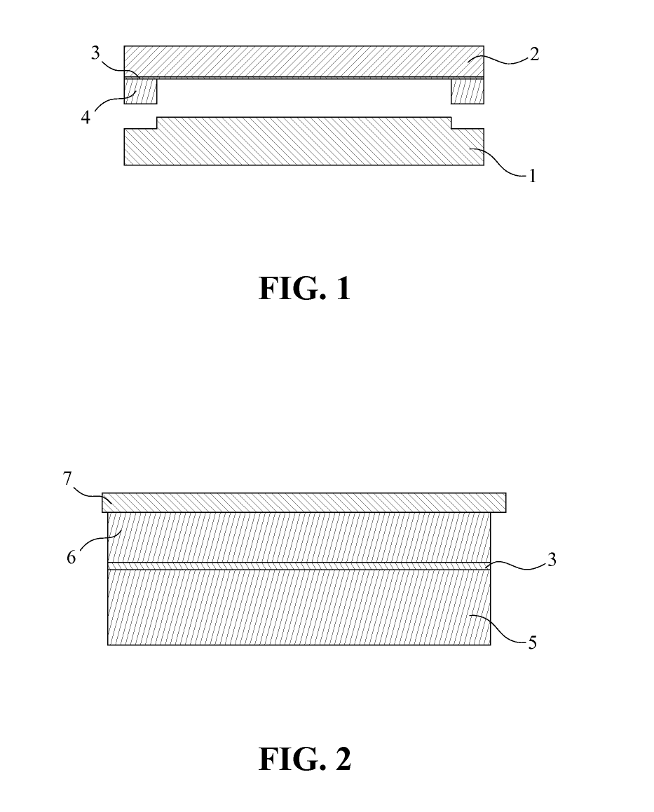

Referring to FIG. 1, a housing structure for an electronic device 1 according to an embodiment of the present invention comprises a composite material panel 2. An inner surface of the composite material panel 2 is coated with a film medium layer 3. One surface of the film medium layer 3 is adhered to the inner surface of the composite material panel 2, and the other surface of the film medium layer 3 is adhered with a plastic member 4.

According to the present invention, a method for manufacturing a housing structure for an electronic device 1 comprises the following steps:

A step of performing: A sheet-like composite material is stacked, according to a required thickness and strength, to form a composite material stacked layer 5 (see FIG. 2). The composite material may be one of a carbon fiber composite material, a glass fiber composite material, and resin composite material.

A step of film adhering: A hot melt adhesive film 3 is adhered on one surface of the composite material stacked layer 5. The hot melt adhesive film 3 has a thickness of 0.01-0.2 mm.

A step of air pressure forming: The composite material stacked layer 5 is put in a mold, and the surface of the composite material stacked layer 5 adhered with the hot melt adhesive film 3 is faced upwardly. A counterpart block 6, which may be made of silicon or metal material, is installed to completely press on the surface of the composite material stacked layer 5 adhered with the hot melt adhesive film 3. A sealing film 7 is coated on a top of the counterpart block 6. Then the mold is closed. Afterwards, the mold is heated and a mold cavity of the mold is simultaneously vacuumed to a pressure of −0.01˜−0.1 Mpa. When the temperature reaches 120° C., the mold cavity is inflated with air at a pressure 3˜15 kg/cm². The air pressure presses on to the top of the counterpart block 6 and further to the composite material stacked layer 5 adhered with the hot melt adhesive film 3. After heating for 10 minutes and followed by cooling for 6 minutes, the mold is opened to obtain a solidified composite material panel 2 with a desired shape. The hot melt adhesive film 3 is adhered on one surface of the composite material panel by way of being melted by heating and then solidified by cooling.

A step of shaping: The composite material panel 2 is shaped by mold punching or computer numerical control machining to a desired shape and dimension.

A step of injection molding: A plastic member 4 is injection-molded on the hot melt adhesive film 3 of the composite material panel 2, so as to be configured a housing structure for an electronic device.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A housing structure for an electronic device, comprising:
a composite material panel, wherein an inner surface of the composite material panel is coated with a film medium layer, one surface of the film medium layer is adhered to the inner surface of the composite material panel, and the other surface of the film medium layer is adhered with a plastic member.

2. The housing structure according to claim 1, wherein the film medium layer is a hot melt adhesive film.

3. The housing structure according to claim 1, wherein the film medium layer has a thickness of 0.01-0.2 mm.

4. The housing structure according to claim 1, wherein the composite material panel is one of a carbon fiber composite material panel, a glass fiber composite material panel, and a resin composite material panel.

5. A method for manufacturing a housing structure for an electronic device, comprising the steps of:
A step of performing, stacking a sheet-like composite material, according to a required thickness and strength, to form a composite material stacked layer;
a step of film adhering, adhering a hot melt adhesive film on one surface of the composite material stacked layer;
a step of forming: putting the composite material stacked layer adhered with the hot melt adhesive film in a mold to be heated and pressurized, such that the composite material stacked layer is formed as a composite material panel with a desired shape, and the hot melt adhesive film is completely melted and adhered on one surface of the composite material panel; and
a step of injection molding: injection molding a plastic member on the hot melt adhesive film of the composite material panel, so as to be configured as the housing structure for an electronic device.

6. The method according to claim 5, wherein the step of forming is an air pressure forming, wherein the air pressure forming comprises the following steps:
the composite material stacked layer is put in a mold, and the surface of the composite material stacked layer adhered with the hot melt adhesive film is faced upwardly;
a counterpart block is installed to completely press on the surface of the composite material stacked layer adhered with the hot melt adhesive film;
a sealing film is coated on a top of the counterpart block;
the mold is closed;
the mold is heated and a mold cavity of the mold is simultaneously vacuumed to a predetermined value of pressure, when the temperature reaches a predetermined value, the mold cavity is inflated with air; the air pressure presses on to the top of the counterpart block and further to the composite material stacked layer adhered with the hot melt adhesive film;
after heating for a period of time and followed by cooling, the mold is opened to obtain a solidified composite material panel with a desired shape, wherein the hot melt adhesive film is adhered on one surface of the composite material panel by way of being melted by heating and then solidified by cooling.

7. The method according to claim 5, wherein after the step of forming and before the step of injection molding, the composite material panel is shaped to a desired shape and dimension.

8. The method according to claim 7, wherein the composite material panel is shaped by one of mold punching and computer numerical control machining.

9. The method according to claim 5, wherein in the step of film adhering, the thickness of the adhered hot melt adhesive film is 0.01˜0.2 mm.

10. The method according to claim 5, wherein the composite material is one of a carbon fiber composite material, a glass fiber composite material, and resin composite material.
